(19) United States
(12) Patent Application Publication
(10) Pub. No.: US 2025/0093421 A1
(43) Pub. Date: Mar. 20, 2025

(54) SYSTEM FOR BATTERY TESTING

(71) Applicant: Anthony Elliott, Myrtle Beach, SC (US)

(72) Inventor: Anthony Elliott, Myrtle Beach, SC (US)

(21) Appl. No.: 18/941,345

(22) Filed: Nov. 8, 2024

Related U.S. Application Data
(60) Provisional application No. 63/583,435, filed on Sep. 18, 2023.

(51) Int. Cl. G01R 31/371; G01R 31/3835; G01R 31/392

(52) U.S. Cl. CPC G01R 31/371; G01R 31/3835; G01R 31/392

(57) ABSTRACT

A system for determining the charge status of a battery to check whether the battery is healthy or dead. The system includes a probe to measure one or more parameters of the battery, such as voltage. The system further includes a user device configured to receive measured values from the probe. The user device includes an interface module and a control module. An interface rendered by the interface module can receive specifications of the battery and present the charge status. The control module can analyze the measured values of different parameters with reference to the specifications of the battery.

### CROSS-REFERENCE TO RELATED APPLICATIONS

This application claims priority from a U.S. Provisional Patent Application No. 63/583,435, filed on Sep. 18, 2023, which is incorporated herein by reference in its entirety.

### FIELD OF INVENTION

The present invention relates to a system for battery testing, and more specifically, the present invention relates to a smartphone-based system and method for battery testing.

### BACKGROUND

Portable devices have become common in day-to-day lives because of their portability and ease of use. Batteries power these portable devices, and thus the batteries play a significant role in the increased adoptability of the portable device. Different types of batteries are known to be used in portable devices including disposable and rechargeable batteries. Disposable batteries are quite common in remote controls, toys, clocks, medical devices, and the like. Typically, multiple batteries are used in one device. The disposable batteries offer an advantage that the consumed batteries can be simply replaced with new ones. However, portable devices lack any means to detect the charge status of disposable batteries. Even in the case of rechargeable and removable batteries, the portable device may not have the circuitry to check the status of the battery. Thus, if the device stops working, replacing the batteries is the first step in troubleshooting the nonfunctional device.

Also, when batteries are used interchangeably, a lot of batteries may pile up. This pile-up of batteries may include charged batteries, partially charged and functional batteries, and dead batteries. It is difficult to separate good batteries from bad batteries.

A need is therefore directed to a system and method for testing the charge status of batteries.

### SUMMARY OF THE INVENTION

The following presents a simplified summary of one or more embodiments of the present invention in order to provide a basic understanding of such embodiments. This summary is not an extensive overview of all contemplated embodiments and is intended to neither identify key or critical elements of all embodiments nor delineate the scope of any or all embodiments. Its sole purpose is to present some concepts of one or more embodiments in a simplified form as a prelude to the more detailed description that is presented later.

The principal object of the present invention is therefore directed to a system and method for testing batteries.

Another object of the present invention is that the system may be smartphone-based.

Still, another object of the present invention is that different types of batteries can be tested.

Yet another object of the present invention is that the process of testing the battery is easy.

In one aspect, disclosed is a system for determining the charge status of a battery, the system includes a probe configured to measure one or more parameters of the battery; and a user device configured to receive measured values of the one or more parameters, wherein the user device comprises an interface module and a control module incorporated in a memory of user device. An interface rendered by the interface module is configured to receive specifications of the battery and present the charge status. Wherein the control module is configured to analyze the measured values of the one or more parameters with reference to the specifications of the battery.

In one aspect, the user device is a smartphone configured to connect to the probe through a USB port.

In one aspect, the user device is a smartphone configured to connect to the probe through an AUX port.

In one aspect, the probe is in a form of a headphone and configured to wirelessly couple to the user device.

In one aspect, the one or more parameters comprise the voltage of the battery.

In one aspect, the output screen is configured to show either a first icon or a second icon, wherein the first icon indicates a healthy battery, and the second icon indicates a dead battery. The output screen is further configured to show a charge level of the battery.

In one aspect, disclosed is the method for determining a health of a battery, the method comprises receiving specifications of a battery, through an input screen of an interface rendered on a user device; presenting instructions to use a probe based on the specifications of the battery, wherein the probe is configured to measure one or more parameters of the battery; receiving measured values of the one or more parameters of the battery; and determining health of the battery by analyzing one or more parameters with reference to the specifications of the battery.

### BRIEF DESCRIPTION OF DRAWINGS

The accompanying figures, which are incorporated herein, form part of the specification and illustrate embodiments of the present invention. Together with the description, the figures further explain the principles of the present invention and enable a person skilled in the relevant arts to make and use the invention.

FIG. 1 is a block diagram showing the architecture of the system, according to an exemplary embodiment of the present invention.

FIG. 2 shows an input screen of the interface rendered on a smartphone, according to an exemplary embodiment of the present invention.

FIG. 3 shows an output screen of the interface, according to an exemplary embodiment of the present invention.

### DETAILED DESCRIPTION

Subject matter will now be described more fully hereinafter with reference to the accompanying drawings, which form a part hereof, and which show, by way of illustration, specific exemplary embodiments. Subject matter may, however, be embodied in a variety of different forms and, therefore, covered or claimed subject matter is intended to be construed as not being limited to any exemplary embodiments set forth herein; exemplary embodiments are provided merely to be illustrative. Likewise, a reasonably broad scope for claimed or covered subject matter is intended. Among other things, for example, the subject matter may be embodied as methods, devices, components, or systems. The following detailed description is, therefore, not intended to be taken in a limiting sense.

The word “exemplary” is used herein to mean “serving as an example, instance, or illustration.” Any embodiment described herein as “exemplary” is not necessarily to be construed as preferred or advantageous over other embodiments. Likewise, the term “embodiments of the present invention” does not require that all embodiments of the invention include the discussed feature, advantage, or mode of operation.

The terminology used herein is to describe particular embodiments only and is not intended to be limiting to embodiments of the invention. As used herein, the singular forms “a”, “an” and “the” are intended to include the plural forms as well, unless the context clearly indicates otherwise. It will be further understood that the terms “comprise”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

The following detailed description includes the best currently contemplated mode or modes of carrying out exemplary embodiments of the invention. The description is not to be taken in a limiting sense but is made merely to illustrate the general principles of the invention since the scope of the invention will be best defined by the allowed claims of any resulting patent.

The invention described pertains to a system and method for determining the health of a battery. The system can detect whether a battery is functional or not i.e., the charge level of the battery. The system can inform whether the batteries need to be replaced with new ones for an electronic device. The system can test different types of batteries through an interactive and easy-to-understand interface.

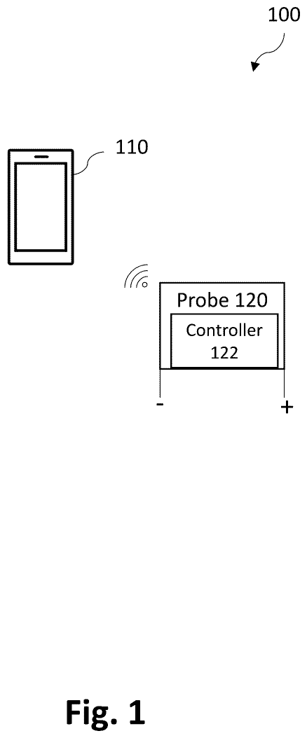

Referring to FIG. 1 is a block diagram showing the architecture of system 100. The system 100 may include a user device 110 and a probe 120. The user device may connect to the probe through a wired connection or a wireless connection. The user device can be any portable computing device that includes a processor for processing instructions stored in memory. The user device can also include an input module for receiving input from the user. Such input can be in the form of a touch display, mouse, stylus, keyboard, touchpad, and the like. The user device may also include a display for presenting information to the user, for example, an LCD screen. The user device may also include a network circuitry for connecting to the network. The user device may also include a camera to capture a photograph of an object including bar codes. Examples of the user device may include a smartphone, a desktop computer, a laptop, a workstation, and the like. Preferably, the user device may be a smartphone.

The user device may connect to the probe through a wired connection or a wireless connection. In the case of a wired connection, the user device may have a suitable port for connecting the wires. Examples of such a port include an AUX port or a USB port. Typically, a smartphone has at least the AUX port or the USB port. For wireless connection, the user device may include suitable wireless circuitry, such as, but not limited to, Bluetooth®, Wi-Fi, NFC, and the like.

The probe 120 may include a controller 122, a positive terminal, and a negative terminal. The controller is configured to detect the charge status of a battery. For example, the controller may detect at least a voltage between the positive and negative terminals of a battery. The controller may measure one or more parameters of the battery including the Voltage. The controller can send measurements in the form of signals to the user device. The terminals may be flexible, which allows for checking different types of batteries and the same batteries of different sizes. For example, the same probe can be used for AA and AAA batteries. The same probe may also be used for coin-shaped batteries.

In certain implementations, the probe may be in the form of headphones with a USB or AUX port. Wireless headphone-like probes are also within the scope of the present invention.

The system may also include a memory incorporating an interface module and a control module. The control module upon execution by a processor can determine the status of the battery based on signals received from the probe. The interface module upon execution by the processor can render an interface on the user device for interacting with the user.

The term module as used herein and throughout this disclosure refers to software, a program code, a set of rules or instructions, and the like in one or more computer-readable languages including graphics, which upon execution by the processor performs one or more steps of the disclosed methodology. Also, operations may be described as a sequential process, some of the operations may be performed in parallel, concurrently, and/or in a distributed environment, and with program code stored locally or remotely for access by single or multi-processor machines. In addition, in some implementations, the order of operations may be rearranged without departing from the spirit of the disclosed subject matter.

One or more modules may be implemented on a user device. One or more modules may also be implemented in the form of servers, which include cloud servers. The servers can be placed in one location or geographically dispersed.

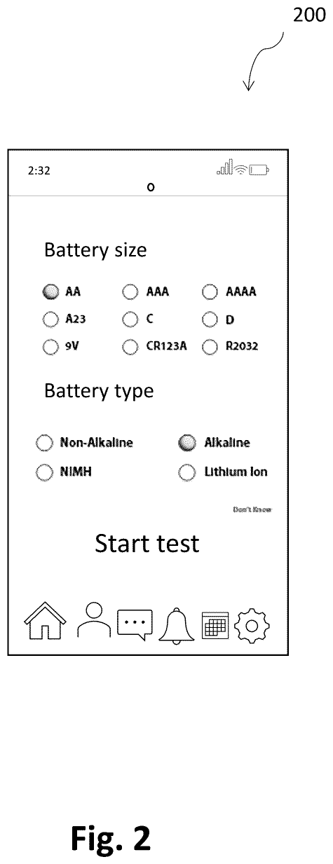

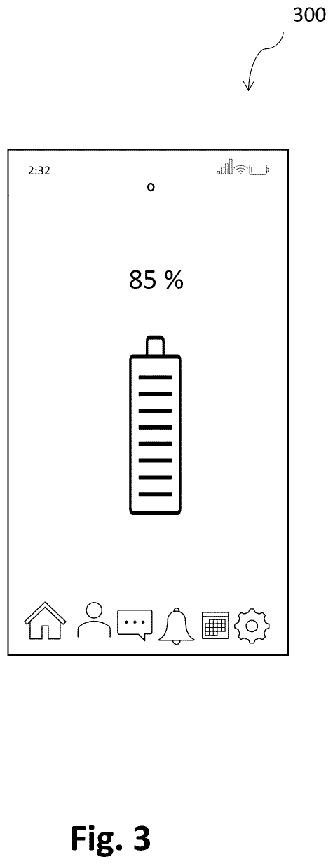

The interface may include a series of screens, as shown in FIGS. 2-3, which in continuation can provide information as well as receive information from the user and execute one or more steps of the disclosed methodology. The interface can be dynamic and allows switching between sections, screens, pages, and the like quickly and easily. The interface can be provided as an application software that can be installed on the user device.

The application software can be developed for Android™, iOS, and any other known operating platform for mobile devices. The application software can be made available through a distribution service provider, for example, Google Play™ operated and developed by Google, and the app store by Apple. In addition to the application software, a website-based interface can also be provided through the World Wide Web. The application software can also be provided for the desktop environment, such as Windows™, Linux, and macOS. The user interface may permit interaction with a user through the user device, wherein information can be presented within the user interface by the system and information can be received by the system from the user.

In use, the system through an input screen of the interface can receive specifications of the battery to be tested. For example, the system can receive specifications as a 1.5 V AA battery. FIG. 2 shows the input screen 200 of the interface for inputting the specifications of the battery. The user can manually type the values, for example, 1.5 in a text field. The user may be presented with several options from which the user may select the battery type. For example, the screen 200 shows an upper section in which different battery types are shown in the form of icons and a lower section which includes capacities of the batteries. The user can select AA from the top section and 1.5 V from the lower section to specify the battery type. Similarly, other battery types can also be specified. The control module may also analyze images of a battery to know its speciation. For example, the control module can receive one or more images of the battery through the interface and camera of the user device. Thereafter, the control module may analyze one or more images to determine the specifications of the battery. Any information that may not be interpreted by the control module from the image may be manually received by the control module.

Once the input information is received, the system may present a second screen showing instructions to apply the probe. The instruction may be in the form of text with or without graphics to better understand the instructions. The probe can then measure one or more parameters of the battery, such as voltage, and send the measured values to the control module. The control module can compare the measured values against the specifications of the battery as input through the input screen to determine the status of the battery. The system can then show the status of an output screen 300. The output screen may show whether the battery is functional or not. Suitable color codes and graphics can also be used to show the battery status. For example, a red color may indicate a dead battery while a green color may indicate a functional battery. A smiley may indicate a charged (functional) battery while a sad smiley may indicate a dead battery. The output screen may also show the charge level of the battery. The charge level may be shown in the form of a percentage. For example, 56% of the battery life remains. The charge level may also be indicated in the form of bars. The control module may also analyze the battery life remaining and display the same using the output screen.

The control module may also receive information about the device, in which the battery is to be used, to determine the remaining life of the battery. The information may include the power requirements of the device. Such information of the device may be manually input by the user or interpreted by the system through images of the device. The control module can then check one or more parameters of the battery against the power requirements of the device to determine whether the batteries need to be replaced. For example, the system can determine that the batteries are not functional for the first device but will work for a second device, wherein the power requirements of the second device are less than those of the first device.

It is to be noted that the system is used to measure the status of external batteries and not the built-in battery. For example, the disclosed system may not be used to check the built-in battery of the user device. The probe may be separate from the user device.

The foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above-described embodiment, method, and examples, but by all embodiments and methods within the scope and spirit of the invention as claimed.

What is claimed is:

1. A system for determining a charge status of a battery, the system comprising:
a probe configured to measure one or more parameters of the battery; and
a user device configured to receive measured values of the one or more parameters, wherein the user device comprises an interface module and a control module incorporated in a memory of user device,
wherein an interface rendered by the interface module is configured to receive specifications of the battery and present the charge status,
wherein the control module is configured to analyze the measured values of the one or more parameters with reference to the specifications of the battery.

2. The system of claim 1, wherein the user device is a smartphone configured to connect to the probe through a USB port.

3. The system of claim 1, wherein the user device is a smartphone configured to connect to the probe through an AUX port.

4. The system of claim 1, wherein the probe is in a form of a headphone and configured to wirelessly couple to the user device.

5. The system of claim 1, wherein the one or more parameters comprise a voltage of the battery.

6. The system of claim 1, wherein an output screen is configured to show either a first icon or a second icon, wherein the first icon indicates a healthy battery, and the second icon indicates a dead battery.

7. The system of claim 1, wherein an output screen is further configured to show a charge level of the battery.

8. A method for determining a health of a battery, the method comprises:
receiving specifications of the battery, through an input screen of an interface rendered on a user device;
presenting instructions to use a probe based on the specifications of the battery, wherein the probe is configured to measure one or more parameters of the battery;
receiving measured values of the one or more parameters of the battery; and
determining the health of the battery by analyzing the one or more parameters with reference to the specifications of the battery.

9. The method of claim 8, wherein the user device is a smartphone configured to connect to the probe through a USB port, wherein the method further comprises:
connecting the probe to the smartphone.

10. The method of claim 8, wherein the user device is a smartphone configured to connect to the probe through an AUX port, wherein the method further comprises:
connecting the probe to the smartphone.

11. The method of claim 8, wherein the probe is in a form of a headphone and configured to wirelessly couple to the user device.

12. The method of claim 8, wherein the one or more parameters comprise a voltage of the battery.

13. The method of claim 8, wherein an output screen is configured to show either a first icon or a second icon, wherein the first icon indicates a healthy battery, and the second icon indicates a dead battery.

14. The method of claim 13, wherein an output screen is further configured to show a charge level of the battery.
